(19) United States
(12) Patent Application Publication
(10) Pub. No.: US 2023/0034395 A1
(43) Pub. Date: Feb. 2, 2023

(54) System And Method For Holistic Approach To City Planning

(71) Applicants: Jake Arsenault, Fredericton (CA); Dane Sheppard, Fredericton (CA)

(72) Inventors: Jake Arsenault, Fredericton (CA); Dane Sheppard, Fredericton (CA)

(21) Appl. No.: 17/803,603

(22) Filed: Sep. 9, 2022

Related U.S. Application Data
(63) Continuation-in-part of application No. 16/350,637, filed on Dec. 13, 2018.

(51) Int. Cl. G06F 30/13; G06Q 50/30; G06Q 50/26

(52) U.S. Cl. CPC G06F 30/13; G06Q 50/30; G06Q 50/26

(57) ABSTRACT

A system for holistic approach to city planning, comprising a transportation calculator including a computer and a display screen displaying a street map of a city, and icons of structural elements of that city on the street map, including at least one icon of a structural element whose location being under planning in that city; a selector for selecting a proposed new location on the street map for the structural element whose location being under planning; and for selecting a go signal. The transportation calculator is configured for simultaneously displaying icons of directly-affected commuters moving along the best routes, and icons of indirectly affected and unaffected commuters moving along respective routine commutes upon selecting the go signal; and a clock associated with the transportation calculator for displaying icons of commuters moving along best routes and routine commutes according to itinerary of each of these best routes and routine commutes.

This is a Continuation-In-Part Application of application Ser. No. 16/350,637, filed on Dec. 13, 2018

### FIELD OF THE INVENTION

This invention pertains to city planning, and more particularly, it pertains to a city planning tool, in which some elements of a city's infrastructure are moved and set by a pointer or touch-screen mode on a computer screen, and the corresponding movement pattern of the city's citizens is illustrated as a perceivable animated progression of indicia on a city map.

### BACKGROUND OF THE INVENTION

City planning softwares are used for studying municipal choices and consequences. The inter-relations between the factors involved are in most cases impossible to be calculated by pen and paper only. For examples, consideration must be given to real estate values, population distribution, public health, municipal infrastructure, bus routes and bus fleets, environment, global air-quality initiatives, city budget, neighbourhood covenants, city by-laws, etc.

A city can be considered as a living entity, comprising structural elements and movement of citizens to and from and along the city's elements. Movement of citizens throughout the city is often the major issue in city planning. Movement of citizens throughout a city is considered as an imprecise science. Sometimes, a slight renovation to the city's infrastructure causes unforeseen traffic delays, and other times, citizens find better ways on their own without city staff's intervention. Therefore it is believed that a good city planning software must take a holistic approach to city planning.

In a holistic approach to city planning, all the city's citizens, their personal attributes and habits must be considered. For examples, babies are brought to a babysitter before work hours; some families have only one car; some people travel only once per week to go to church or to a grocery store, and some commuters live away from a bus route. In a holistic approach to city planning, as many details as possible about household characteristics and the citizens' daily commutes and itineraries should become part of the planning exercise.

In a holistic approach to city planning it is also desirable to use a software that depicts the commuter icons movement in a realistic way. For examples it is desirable to present a displayed simulation wherein:
a) Commuter icons movement and speed are independent from one commuter to the other, as opposed to batch movement;
b) Commuter icons movement must decelerate smoothly when traffic density increases, as opposed to a set deceleration value at every street node; and
c) Commuter icons movement deceleration rate must be different from one commuter to the other.

In the past, city planning have been done by city's staff and trained professionals, using planning softwares and presenting their findings to city officials in a formal conference setting.

In a holistic approach to city planning, it is believed that a software must be accessible to people without a computer technology background. It is believed that realistic icon movement presented in a city planning software as mentioned in a), b) and c) above is an important aspect of a software that makes the software more acceptable by people without a computer technology background.

Examples of documents related to city planning softwares found in the prior art are briefly described herein below:

U.S. Pat. 4,962,458 issued to Rik A. Verstraete on Oct. 9, 1990; discloses a route planner, in which a road network is divided in road segments and junctions. The road network is also divided in cell blocks, the position of which is identified by their connecting road segments and junctions. Tables are made of blocks, road segments in each block, and starting and ending blocks of each road segment.

U.S. Pat. No. 5,329,464 issued to Zarko Sumic et al., on Jul. 12, 1994; discloses a utility layout design system, that combines data available in a typical geographic information systems (GIS) and rule-based expert system.

U.S. Pat. No. 5,818,737 issued to Wilson W. On et al., on Oct. 6, 1998; discloses a municipality development method. A modelling and simulation module provides a range of future scenarios for the municipality based upon the date inputted and given assumption sets and decision options. The output provided by the modelling and simulation modules may be in the form of two- or three-dimensional visual presentations on an especially equipped multiple, computer-driven, projector screen room or may be in the form of a printed media for binding and distribution with screen images combined with text. Special software for presentation purposes to staff or at public meetings may be employed to portray and visualize specific or simulated presentations. The modelling and simulation system provides a method for projecting the effect upon a municipality of present and proposed decisions by decision-makers of the municipality.

U.S. Pat. No. 7,970,642 issued to Alex Anas on Jun. 28, 2011; discloses computer-based system for implementing land use and transportation planning. Based on actual regional economic and land-use data, the system generates a new economic and land-use forecast and includes a proposed traffic network to support the forecasted economic and land-use forecast.

U.S. Pat. No. 8,392,239 issued to Scott Keith Fehnel et al., on Mar. 5, 2013; discloses a computer system for forecasting demand and availability of resources of a geographic region. More specifically, the system can display forecasted traffic density as a result of some changes in the geographic region.

U.S. Pat. No. 9,778,051 issued to Hoang Tam Vo et al., on Oct. 3, 2017; discloses a route planning system. This planner identifies the shortest route between an origin and a destination.

U.S. Pat. No. 9,953,113 issued to Qi Yang et al., on Apr. 24, 2018; disloses a traffic data management and simulation system. The simulation system can simulate dynamic traffic flows over a road network, such as vehicles following each other, lane changes and different individual driving behaviour models.

Although traffic flow simulation and city planning tools are well known in the art, the input variables to these systems must be formulated in compliance with a set of expected criteria in order to obtain relevant results. The algorithms of a software are designed to accept specific inputs in order to provide realistic answer. These algorithms are often limited to few expected scenarios, wherein a solution is heavily influenced by commonplace assumptions. For example, an irrational simulation would be provided if a requester assumes that every citizen has access to a bus stop, that every citizen drives a car, or every citizen is willing to take a bus and not to drive. Therefore, in the past, the use of city planning softwares has been limited to the experts.

It is believed that there remains a market demand for a city planning software that is easy to operate with minimum tutorial. There is a need for a rapid city sketch tool that can be used by mayors, councillors and by the general public, regardless of educational background. It is believed that there is a market demand for a city planning software which can be downloaded on demand to the personal computer of real estate developers, taxi operators, fire protection officials and concerned citizens. It is believed that there is a need for a city planning software that is fun and engaging to operate, and that can be installed for display in a shopping mall and experimented with by people stopping by. There is a need for a city planning software that operates like a computer game; a civic engagement tool that can retain the attention of users, through interaction, animation and visualization of the consequences of their choices.

### SUMMARY OF THE INVENTION

In the present invention, there is provided a visual transportation calculator as applied to city planning that presents an accurate rendition of a transportation model in motion. Commuter icon movements are displayed in a realistic manner.

In a first aspect of the present invention, there is provided a system for holistic approach to city planning. This system incorporates a visual transportation calculator, comprising:
a computer and a display screen being configured for generating an animated display, displaying a street map of a city, icons of commuters moving along streets of the street map and icons of structural elements of that city on the street map; including at least one icon of a structural element whose location being under planning in that city;
a database of attributes of households in that city, including respective itineraries, departures and destinations of routine commutes of commuters in these households;
a selector for selecting a proposed new location on the street map for the structural element whose location being under planning; and for selecting a go signal;
a first calculator selecting directly-affected commuters, indirectly-affected commuters and unaffected commuters amongst all the commuters, relative to the proposed new location, upon selecting the proposed new location; and for calculating best routes for the routine commutes of all directly-affected commuters;
the computer and display screen being also configured for simultaneously displaying, icons of directly-affected commuters moving along the best routes, and icons of indirectly-affected commuters and unaffected commuters moving along respective routine commutes of these indirectly-affected commuters and unaffected commuters, upon selecting the go signal; and
a clock associated with the transportation calculator for displaying icons of commuters moving along the best routes and routine commutes according to itinerary of each commute.

Users of this city planning system can better appreciate the effect of a modification to the city structure, on city life. Movement of all commuters are displayed in a real-time, dynamic mode; toward a city centre in the morning and away from the city centre in the evening. Depending on the new location selected, best routes are no longer limited to the obvious ones. Such holistic approach to city planning promotes the concept that a city is somewhat like a living entity, with unpredictable reactions to changes.

In another aspect of the present invention, there is provided a method of operating a city planning transportation calculator, wherein this transportation calculator comprises a computer and a display screen displaying a street map. The screen displays icons of commuters travelling along streets of the street map. The display comprises at least one icon of a structural element under planning in that city. This icon can be moved by the user to various locations on the map. The computer calculates travel time of commuters from different residential areas to the structural element, or to their respective routine destinations. The streets are divided into relatively short segments defined by nodes. The transportation calculator calculates best routes and commute time in an aggregated manner between every node, for every commuter.

Moreover, the calculation is repeated for every node from the route's origin to a present position, every time a new node is reached. As commuters progress toward their destinations, the numbers of calculations effected for each commuter is comparable to a summation of consecutive numbers, and is also comparable to an exponential distribution. As a result, commuter icons are independently decelerated gradually as they approach their destinations and traffic increases, and the rate of deceleration is different for each commuter. Commuter icons are displayed in a pleasantly stylized representation.

Because of the repeat calculations between every nodes, the results are presented, and the icons are moving, in a somewhat controlled manner. An adjustable display-speed/clock-time ratio is included in the calculations for slowing down the calculation if needed, relative to the clock's rhythm. The resulting display is perceivable as an animated progression of icons on the streets of the street map. In such a display, the user of the visual transportation calculator can visualize the work done by the transportation calculator for every choice made.

In yet another aspect of the present invention, there is provided a method of presenting a city planning project to a citizen. This method comprises the following steps:
displaying to the citizen, a street map of a city, a movable icon of a structural element under planning in that city; icons of commuters in that city including icons of directly-affected commuters travelling to the structural element in that city; and transportation calculator for calculating commute time by all the commuters along routine commutes of these commuters including commutes to the structural element;
requesting the citizen to move the movable icon of the structural element to a new location, and
requesting the citizen to initiate a calculation of the commute time by all commuters;
effecting calculation by street segments of the commute time by each of the commuters along routine commutes of the commuters including commutes to the new location of the structural element;
displaying icons of commuters entering the city street in an aggregate manner along the street segments;
repeating the steps of effecting calculations and displaying icons of commuters and synchronizing a travel of the icons of commuters regardless of the routine commutes including the commute to the new location of the structural element, and regardless of the entry point of the commuters on the street segments.

The present system for holistic approach to city planning serves two purposes. This system is a quick sketch tool for use by city's planning staff, and it is also a fun game-like civic engagement software for use in public places by interested citizens.

The game-like civic engagement tool is configured for generating an animated display comprising three superimposed layers, from which the static elements of a city structure is on a base layer; the icons of commuters is shown in three-dimensional mode on a second layer and textual instructions and information from the computer are shown on a top third layer. The three layers are transparent with icons of commuters and trees being opaque. This animated display is particularly appealing to users of this civic-engagement tool.

This brief summary has been provided so that the nature of the invention may be understood quickly. A more complete understanding of the invention can be obtained by reference to the following detailed description of the preferred embodiment thereof in connection with the attached drawings.

### BRIEF DESCRIPTION OF THE DRAWINGS

A preferred embodiment of the system for holistic approach to city planning according to the present invention is described with the aid of the accompanying drawings, in which like numerals denote like parts throughout the several views, and in which:

FIG. 1 is a sample city map of the visual transportation calculator as viewed on a large screen, in a paused mode;

FIG. 2 is a legend of inherent landmarks shown on the city map of FIG. 1;

FIG. 3 is a legend of travel modes associable with the different responses provided by the preferred visual transportation calculator;

FIG. 4 is a legend of the structural elements, some of which are structural elements that are movable to various locations, for generating new calculation sets;

FIG. 5 is a legend of the different travelling indicia, some of them being movable on the screen along the city streets of the system for holistic approach to city planning according to the preferred embodiment;

FIG. 6 is an enlarged view of the display on the upper centre space of the screen illustrated in FIG. 1, showing the travel mode being selected and considered during a calculation;

FIG. 7 is an enlarged view of the display on the upper left corner of the screen illustrated in FIG. 1, showing a clock and a pause and start buttons;

FIG. 8 is an enlarged view of the display on the right hand side of the screen illustrated in FIG. 1, showing average commute time, greenhouse gas emissions and fuel costs for each calculation set;

FIG. 9 is an enlarged portion of the street map of FIG. 1, illustrating a sample street network with segments and nodes along that street network;

FIG. 10 is the sample street network of FIG. 9, illustrating an exemplified movement of one family from their home to city center;

FIG. 11 is the sample street network of FIG. 10 during the development of a traffic bottleneck, as more families converge simultaneously to the elementary school in that scenario;

FIGS. 12, 13 and 14 illustrates the formation of the bottleneck as illustrated in FIG. 11, and the dissipation of that bottleneck, in a twenty minute interval;

FIG. 15 illustrates the results of a sample query done by the preferred visual transportation calculator, with the elementary school at the location shown in FIGS. 9-14, and while considering all probable commuters in the entire population of that city;

FIGS. 16 and 17 illustrates the calculations of an alternate placement of the elementary school on the city map of the visual transportation calculator;

FIG. 18 is a preferred arrangement of the game-like civic engagement version of the visual transportation calculator according to the preferred embodiment of the preferred invention;

FIG. 19 is a diagram of a first portion of an algorithm for displaying commuters on a display screen moving along city streets travelling to different destinations, in different mode of transportation;

FIG. 20 is a diagram of a second portion of the algorithm to match commuters' activities and priorities to household priorities and resources;

FIG. 21 is a diagram of a third portion of the algorithm for increasing the number of travel time calculations as commuters approach their destinations, for slowing down commuter movements on a display screen.

FIG. 22 is a diagram of a fourth portion of the algorithm for increasing the number of travel time calculations of commuters.

### DESCRIPTION OF THE PREFERRED EMBODIMENT

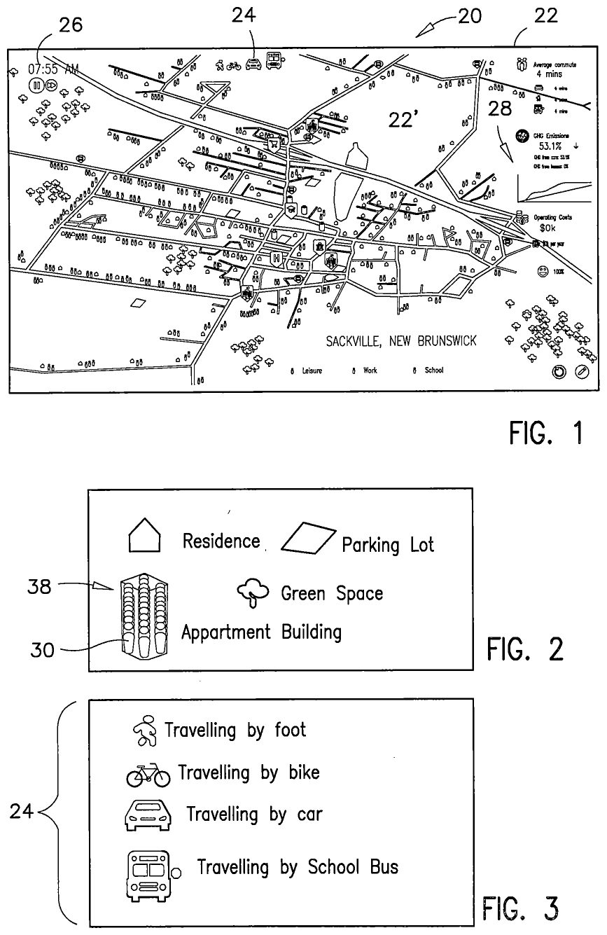

Referring to FIGS. 1 and 2, the system for holistic approach to city planning comprises a visual transportation calculator 20, including a computer (not shown) and a display screen 22 illustrating a city map 22′. The city map 22′ includes streets, institutional buildings and landmarks, and icons of people moving along the streets from a point of departure to a destination. The city map 22′ is built in a conventional manner from geographic information systems. The city map 22′ may be formatted for better visualization on the display screen 22. The composition of the population of that city and its characteristics are built from different data including data obtained from Statistic Canada, utility billings; municipal tax base; traffic history records; census records; intersection traffic counts; transit ridership data; surveys and cell phones tracking data and other data automatically updated by various departments of a municipality.

Based on the data available, the population of the city being studied is divided into a statistically-correct distribution of school-age children, working people, and stay-at-home moms or dads, retired adult, senior citizens, and joint-tenants having the availability to share a vehicle.

A database of household attributes is constructed from the information mentioned above. The database preferably also contains the number of vehicle(s) in each household; age, physical fitness, status and number of all commuters in each household, as well as itineraries, departures and destinations of their routine commutes and intermediate stops along the streets of the city map 22′. The database of household attributes further preferably comprises typical daily activities of all commuters, their place of work, working hours, day-offs, and statistics about probable mode of travel of each commuter, based on distance, cost of travel and habits of a similar population.

The status of every commuters mentioned above, includes whether the commuter is a working parent, a child, a baby, a single adult, a non working adult or a retired individual. The routine commutes as mentioned above include intermediate stops, diversions and back tracks.

The database of household attributes also contains a connection between each commuter and a respective destination along the city map, such than when a commuter is pointed to or touched on a display screen, the destination of that icon is lit up.

In use, icons of people move along the streets of the map 22′, in a most realistic ways. People move from home at a realistic time of the day, to respective place of work, according to population of workers in each location. School-age children move from home to school at realistic time, according to population of students in each school.

Parents stop by a babysitter or the elementary school on their way to work. Teenagers travel by foot, by bike or by bus. Adults travel by car, or by city bus, alone or two by two. Some people stop by a coffee shop on their way to work. Parents stop by the grocery store on their way back home. In the evening, the morning traffic pattern is reversed. And there are individuals with no car, no school bus service, no access to a public bus routes, basically, no transportation option.

The programming of the visual transportation calculator 20 uses available data and statistics to define a most probable number of citizens travelling by foot, by bike, by car or by buses. The transportation calculator 20 assigns a most probable mode of travel to each commuter. The transportation calculator 20 also assigns mixed modes of transportation to some individuals, according to a statistically correct representation of travellers. Examples of mixed modes are: bike and bus; bus and walk; and walk and car-share.

The present approach to city planning displays icons of citizens moving about the streets on the city map 22′ according to the transportation model as modified by the user. When the user moves an icon of a building to a new location, for example, a new transportation model is displayed. That user can then understand that the city is somewhat like a living entity, wherein one change to the structure has effects throughout the entire city.

The present approach to city planning consists of displaying a transport model where traffic congestions are not interpreted as a disease, but as a consequence of structural arrangement inside a city.

In addition to moving an icon of a structural element of a city, a user can enter modifications related to that element. For example, a user can increase or decrease parking fees, change bus routes, modify the spacing of bus stops, add more buses, block a road, adding a bike path, etc.

The approach used in the preferred visual transportation calculator 20 is based on the best route between a specific address and a destination. In a default mode, the speed travelled along that route is calculated according to the four modes 24 of transport available; walking; biking; by car, or by bus. If one of these icons 24 is selected, only that modality is highlighted or displayed.

Although there are four modes of transport illustrated, it will be appreciated that when the preferred visual transportation calculator 20 is used in another city, the modes of transport may include subways, trains, autonomous vehicles, electric cars and scooters for examples.

Icons 30 of commuters are displayed in varying densities of icons. The word density as used herein refers to the number of icons 30 of commuters per unit of street length. Bottlenecks and relaxed highways can thereby be readily identified, by visually interpreting the density of icons at specific locations along the street map.

Each street on the city map 22′ is assigned and classified by a specific street code. A street code takes into account the speed limit on that street and the road condition. The travel speed of each icon is adjusted according to the street code and mode of travel. Time of day is shown on the clock 26 on the upper left corner of the display screen 22. Starting time of day for a display can be selected by the user. For convenience, the clock 26 can be sped up to eight times normal speed.

A display-speed/clock-time ratio is incorporated in the algorithm of the transportation calculator 20 and can be adjusted relative to the clock's rhythm for showing icons of commuters moving at speed that is easily observable on a display screen, and that is perceivable as an expected normal city-driving speed.

The results window 28 depicts the average commute time for citizens travelling on foot, by bike, by car or by buses. Greenhouse gas emission is illustrated in the form of a graph over a desired level. The cost of travel of school buses; operating and fuel costs, is given in thousand dollars per year.

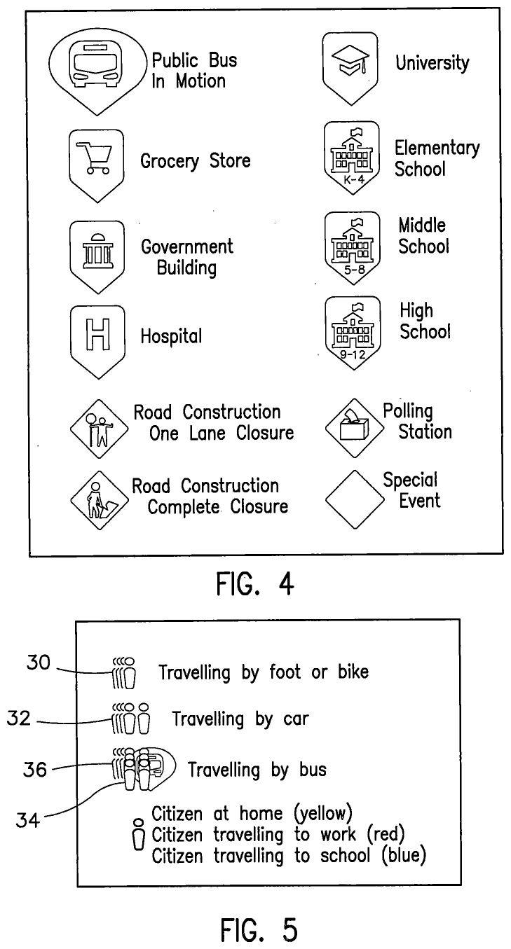

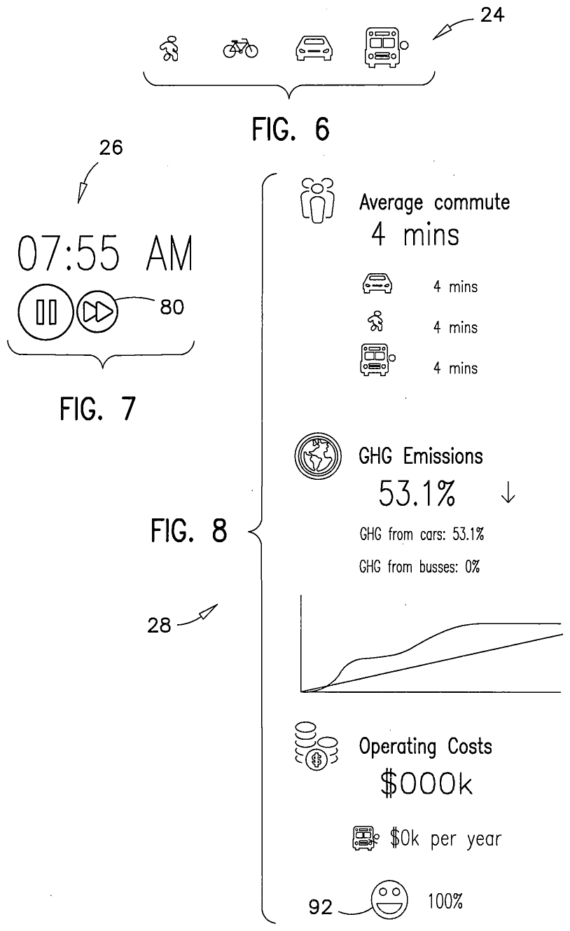

Referring back to FIG. 4, some of the icons shown therein represent the structural element variables. A displacement of one or more of these variables by the user of the preferred transportation calculator 20 becomes criteria for guiding the calculations of the preferred visual transportation calculator 20. In addition to the icons illustrated, the movable structural elements may also include entire streets, subdivisions; sidewalks; bike rental outlets; parking lots; pedestrian corridors, or any other element included in the city's infrastructure.

Referring again to FIG. 5, the icons of commuters and transit infrastructure are the only icons moving during the calculation of a scenario. The present approach to city planning depicts a transport model or system rather than focussing on bottlenecks.

Icons 30 of people travelling on foot or by bike move along the road segments of the map 22′ at a walking speed. Icons of people travelling by car 32 or buses 34 are depicted travelling at a street speed limit, determined by the aforesaid road code and display-speed/clock-time ratio. All people icons travelling along the city streets are illustrated in actual two-dimensional movement as represented by shadow 36. Icons of city buses, including empty busses can also be illustrated in motion along the city street, according to their bus routes and itineraries.

The moving icons are illustrated in different colours; red for people engaging in work-related activities; blue for citizens engaging in institution-related activities (school, hospitals, libraries, etc); and yellow for people currently engaging in errands or leisure-related activities. Colour coding may also be reassigned according to mode of travel, or other commuter feature included in the database of household attributes. People icons change colour based on their intended “primary use” of the city infrastructure. Icons of people going to work and at work are displayed in red, then they change to blue when heading to university for a night class, or yellow when heading home.

Every citizen in the city being studied is represented by an icon. The citizens travelling along the city street are shown in movement along the street, and the citizens not travelling are illustrated in a stand-still mode near their places of residence or near or over their target destinations.

For convenience of the description, the word commuter is used herein to designate any citizen currently travelling to a desired location, including travelling from a residence inside the city limit to a location outside the city, and from a location outside the city to a residence or another destination inside the city. Similarly, the word commute refers to route taken by a commuter to reach his/her destination. Of course, the transportation calculator 20 and display screen 22 report on commuters only when their commutes coincide with any portion of the city's infrastructure.

The visual transportation calculator 20 calculates the travelling time of every commuter, from node to node. Results given are average commute time for the entire travel distance, by mode of travel, for all commuters.

Although many icons of institutional variables are depicted on the map of FIG. 1 and in FIG. 4, only a few of them can be moved by users, according to the immediate plans of that city. For examples, a city plan might include the replacement of an aging building, the construction of a new building to satisfy a growing population, the consideration of a new nature park, new parking areas, exhibition grounds, stadium, service stations, bike trails, transit routes, bus stops, etc. Therefore, some icons can be replaced or added according to the needs of the city for which the preferred visual transportation calculator 20 is being tailored to.

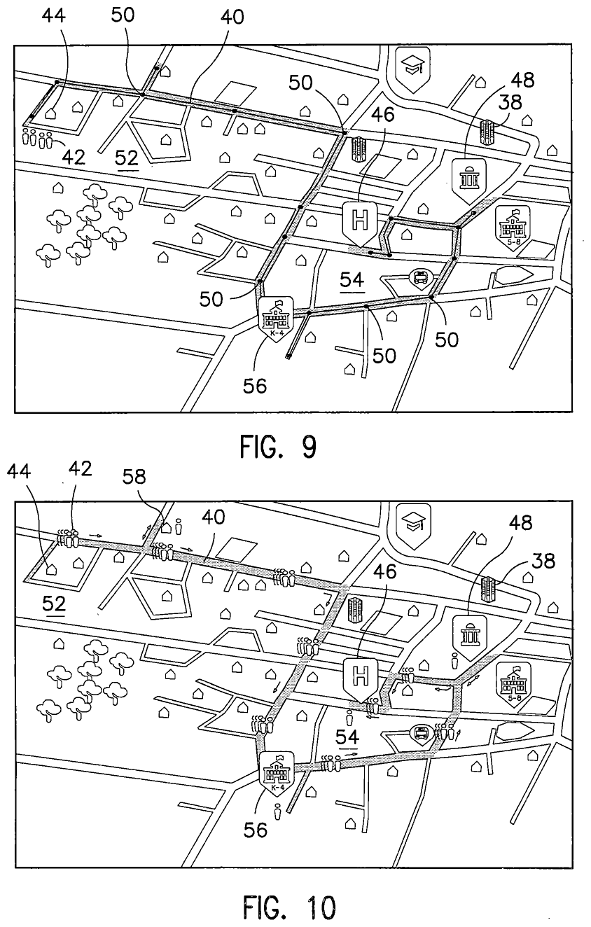

Referring now to FIG. 9, a portion of the city map is illustrated therein to further describe the structure and operation of the preferred visual transportation calculator 20. The route 40 is the usual route or commute of a family of four 42 living at the address shown as label 44. For this example, let us consider that this family has a toddler and a child of elementary school age. The spouse works downtown at the hospital 46 and the husband works at the post office 48 in the city centre. Every segment along the route 40 is defined by nodes 50.

In the map of FIG. 9, region 52 represents a residential area, and city centre is labelled as 54. The circumstances to be considered in the example of FIGS. 9-17, is the construction of a new elementary school 56 to replace an aging building, which has become too small and too expensive to repair.

Referring to FIG. 10, the morning routine of the family 42 of four in FIG. 9 consists of firstly driving to a babysitter at address labelled 58 in FIG. 10, drive back to main street, along route 40 through city centre 54, to the elementary school 56; drop the school-age child to school and continue toward the post office 48. The husband goes to work to the post office 48 and his spouse keeps the car and drives to work at the hospital 46. In real time on the preferred visual transportation calculator 20, the calculations are effected between nodes 50. During the entire travel time, the citizen icons 30 of this family are in motion along the route 40.

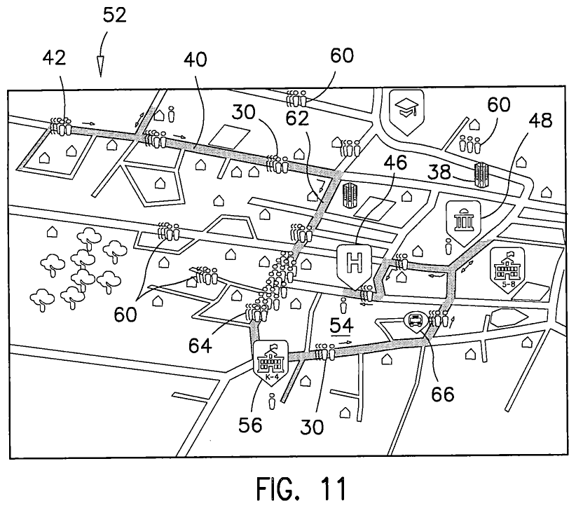

The simplified example illustrated in FIGS. 9 and 10, however occurs rarely in real time. FIG. 11 illustrates a more accurate representation of the morning traffic in that town. People 60 are coming from all directions and merging at different nodes, converging to main street 62 for example, leading to the elementary school 56. As more and more commuters travel this main street 62, a bottleneck 64 is created along main street 62.

As mentioned, city buses 66 are preferably illustrated in motion along with icons 30, 60 of commuters.

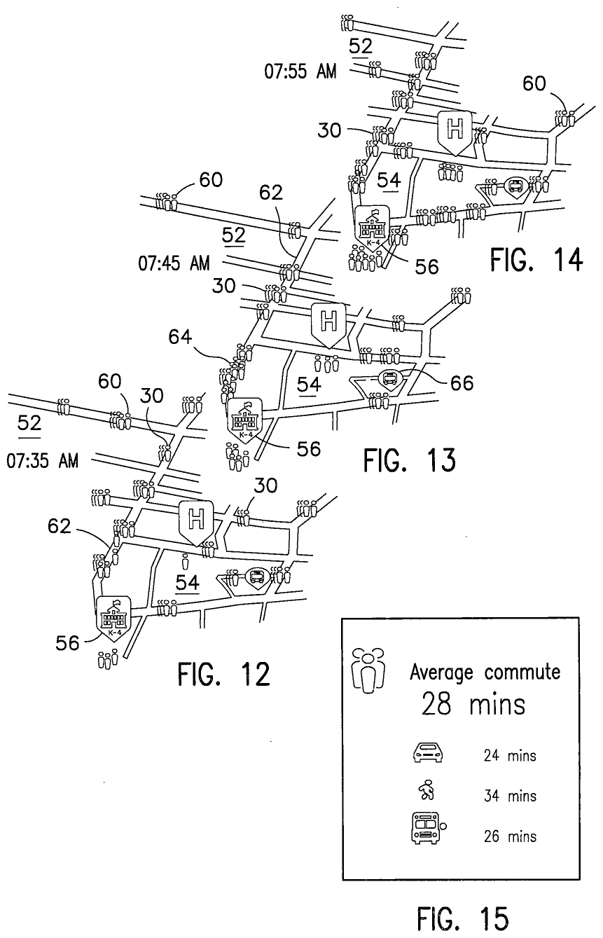

The formation of this bottleneck 64 is illustrated in three images taken at ten minutes intervals in FIGS. 12, 13 and 14.

Because the calculations are effected between nodes 50, and for every commuter in the city being studied, the movement of icons along the street is comfortably observable. Because the computer repeats travel time calculation for every commuter, between every node, the work of the processor increases exponentially as the commuters approach their destinations. The movements of the icons on the street map is inherently slowed down as traffic increases. The display screen 22 of the preferred visual transportation calculator 20 presents a perceivable animated progression of icons 30, 60 along the streets of that city. The movement of the icons is also controlled by a display-speed/clock-time ratio which can be adjusted to illustrate representative icon speed and a steady, visually appealing, progression of icons along the city map. The movement of icons 30, 60 along the streets is entertaining as it depicts real life's indirect travels and consequential delays.

When the entire population of commuters and citizens have reached their destinations, the preferred transportation calculator 20 displays the results on the right hand side of the screen as illustrated in FIG. 15.

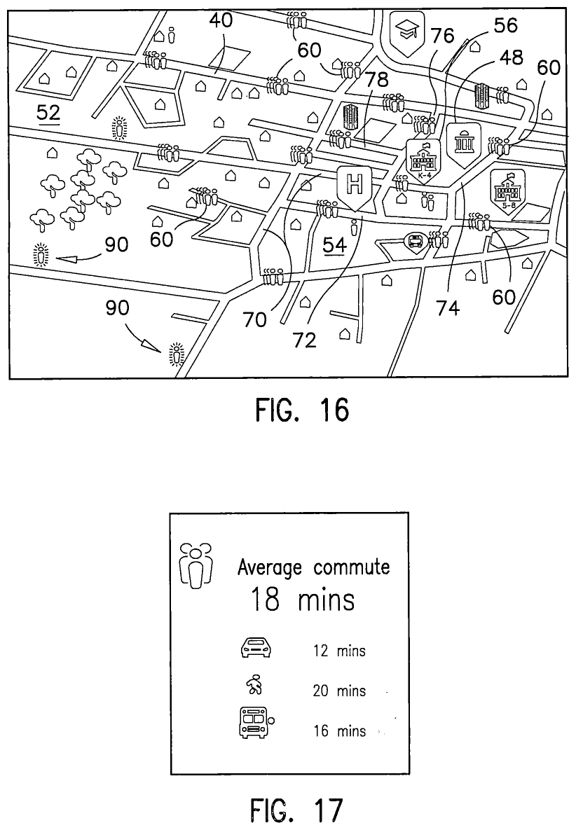

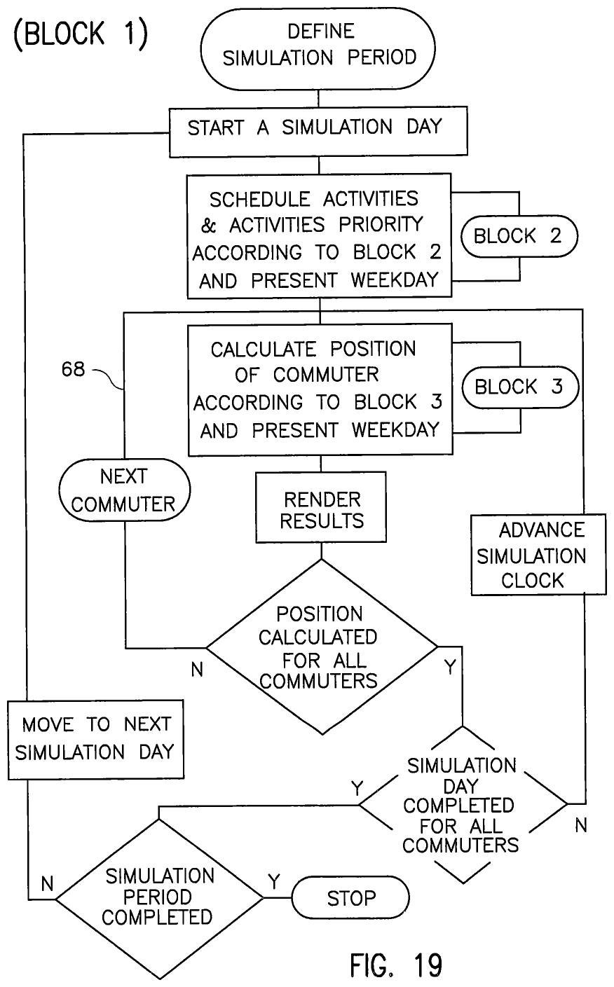

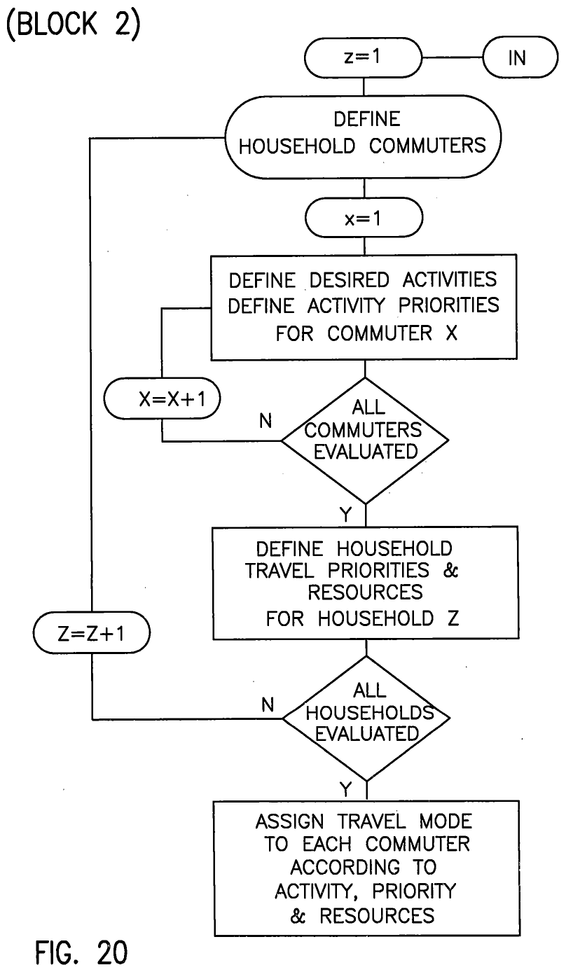

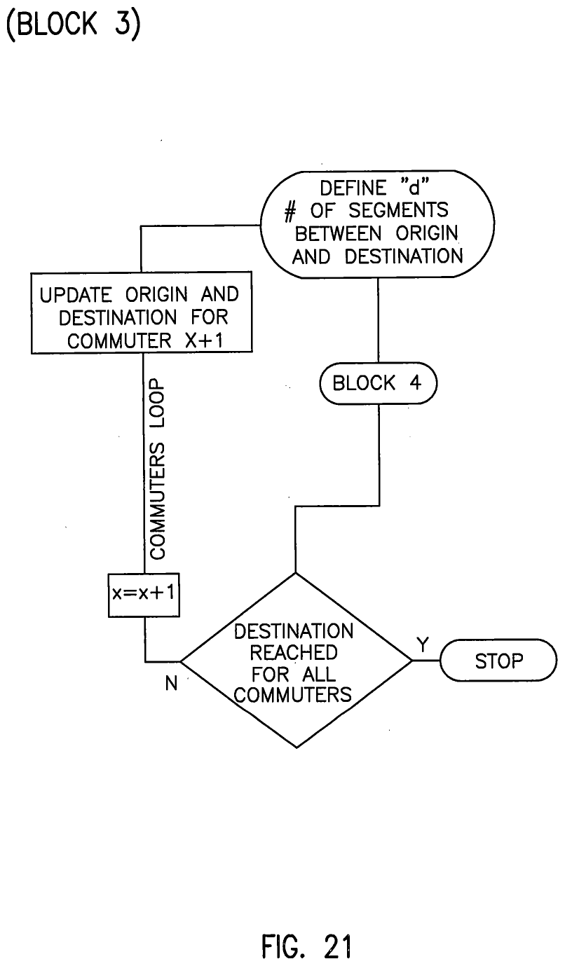

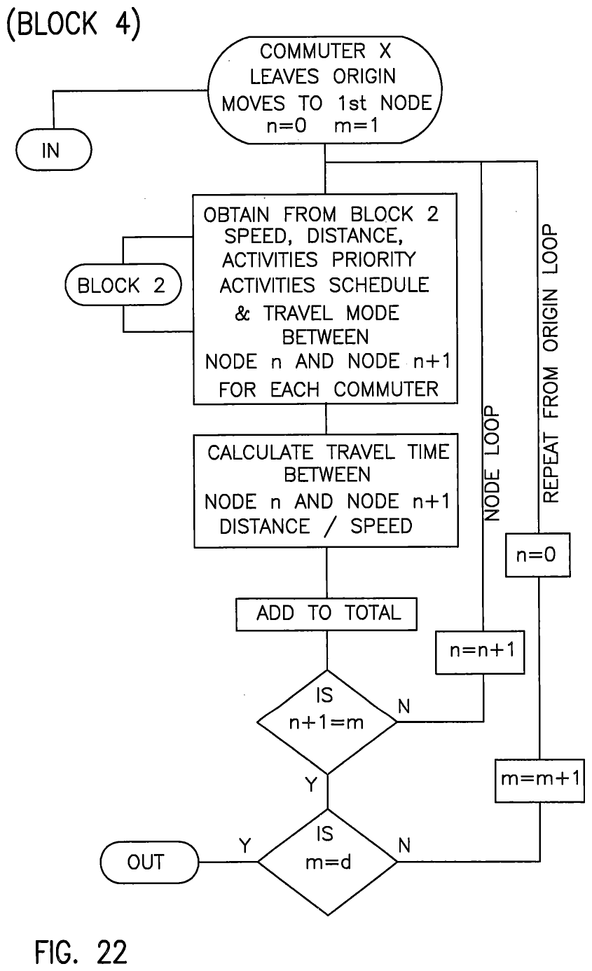

Referring now to FIGS. 16, 17, 18 and 19, diagrams of an algorithm inside the preferred visual transportation calculator 20 are presented. This algorithm is used to slow down the movement of icons of commuters as these commuters approach their respective destinations. For convenience, the entire algorithm is illustrated using four block diagrams.

Block 1 illustrates the main architecture of the algorithm. Simulations are effected one day at the time, taking into account different activities for different day of the week.

In a first step, a loop is made to Block 2 and back, where activities and priorities are assigned to commuter, for each household according to common city life; i.e. school, church, gym, for examples, and age and physical condition of commuters. Activities and priorities are also assigned a mode of travel according to household resources; car, bus, bicycle, distance of travel, for examples.

As simulation progresses, a loop is made to Block 3 and back; and within Block 3, a loop is made to Block 4 and back, where positions and of commuter icons are calculated. The results are displayed on a display screen, and a simulation clock is advanced to keep track of the time of day.

The simulation illustrated in Block 1 is made for every commuter. The inside loop 68 shown in Block 1, for calculating position and displaying results is repeated at a rate of 60 times per second for every commuter, for every second of simulation time. It has been found that such a speed rate provides a very realistic visual rendition of traffic movement.

In Block 2, the label “z” refers to one household and the label “x” refers to one commuter. This portion of the algorithm is called upon to determine properties of commuters and their origin, destination, priority and mode of travel.

In Block 3, the label “d” refers to the number of segments between the origin and destination of every commuter. This Block 3 loops into Block 4 to calculate travel time between nodes along the travel routes, and to repeat the effected calculations from origin to present position every time a commuter icon moves to a new position, and the new position becomes the present position. The label “n” refers to one node along a city route, and label “m” refers to the number of segments travelled to present position. The label “m” keep track of the number of segments between origin and present position.

It will be appreciated that an average size city may have 10,000 commuters travelling every morning and evening. In a simulated scenario, the workload of the computer increases 10,000 folds every time these commuters move from one node to the next. By repeating the calculations from origin to present position every time a commuter moves to a new node, causes the calculations to become voluminous. At the 2^{nd} node, 3 calculations are required; at the 3rd node, 6 calculations are required, and at the 10^{th} node, 55 calculations are required. At the 20^{th} node, 210 calculations are required. At the 50^{th} node, 1275 calculations are required. At the 100^{th} node, 5050 calculations are required.

The number of calculations effected in Block 4 can be compared to a summation of consecutive numbers. It is believed that this summation represents an exponential distribution. When the number of commuters increases 10,000 folds at every new node along a route, and the loops in Block 4 executed 60 times per second for each commuter, the workload of the computer increases exponentially as the commuters progress along the travel routes.

As a result, the movement of the commuter's icons is slowed down as these icons approach their destinations. The display speed of the commuter's icons scales inversely with the density of the road network and with the number of commuters. Because results are rendered for every commuter, the speed of all icons is reduced while future positions are being calculated for all commuters. Because results are rendered for every commuter simultaneously with processor's workload, speed reduction is effected gradually between nodes and over nodes, as opposed to an abrupt deceleration at the passing over one node. Also because results are rendered for every commuter, while future positions are being calculated for all commuters, and because street segments are not the same length, the rate of deceleration is slightly different for each commuter icon.

Therefore the speed reduction of any commuter icon on the display screen is independent and specific to that commuter icon. The speed reduction is effected gradually, and the rate of deceleration varies from one commuter to the next. It is believed that a rendition of a simulation using the system for holistic approach to city planning according to the preferred embodiment of the present invention is a depiction representative of reality. It is believed that such features make the preferred system visually realistic, and pleasant to work with.

Referring now to FIGS. 16 and 17, a new scenario is illustrated. The elementary school 56 has been relocated down town 54 between the hospital 46 and the post office 48. As a result, the bottleneck on main street 62 has been eliminated. Citizens can travel from the residential area 52 to the elementary school 56 from several different access streets 70-78. A calculation of average commute time for this new location shows reduced average travel time by almost 30%. A further analysis of the icons of commuters in that scenario shows that the number of commuters walking and biking has increased. This alternate mode of travel, although slower than cars and buses, reduces traffic load on city streets, thereby reducing overall travel time.

Although the example illustrated above shows a reduced travel time, stakeholders of a city planning exercise generally care more about greenhouse gas emissions and active transportation such as walking and biking which promotes health benefits.

In fact, it is believed that in general, city officials establish their priorities as follows by order of importance:

1) Economic impact;

2) Active transportation for promoting health of citizens;

3) Greenhouse gas emissions;

4) Commute time; and 5) Traffic loads.

The preferred transportation calculator 20 provides all five aspects of city planning.

The transportation calculator 20 calculates the best routes to the new location, for all directly-affected commuters travelling to the new location. Based on the best routes, distance of travel, age of commuters; physical fitness of commuters, statistics, and availability of infrastructure, the transportation calculator 20 also makes assignments of traffic modes to each commuters. As can be seen in the above example, resulting travel time in one scenario is rather unpredictable before every commuters has reached a respective destination.

The display of commute time in FIG. 17 can be updated at every node, for a selected commuter, or when that commuter reaches the final destination, or upon a return home after a day at work for example. The display can be updated at specific time intervals, such as from daybreak to the end of the morning rush, for example.

In a public consultation setting, the user of the preferred visual transportation calculator 20 can drag the icon of the elementary school 56, by light pointer, by motion-translation mouse or by touch-screen mode, and similarly touch the start button 80 under the clock 26, as shown in FIG. 7.

When the start button 80 is activated, the citizen icons 30 affected by the change, referred to herein as directly-affected commuters, are set in motion on the map toward the new location. The icons 30 of other citizens, referred to herein as indirectly-affected and unaffected commuters, keep moving along their routine commutes. The user's can appreciate the computer's work by visually monitoring an animated progression of icons filling up the streets and converging toward their destinations.

The expression indirectly-affected commuters and unaffected commuters used herein refers to commuters of which their route is inadvertently affected by an increase in traffic load along their routine commute, due to the aforesaid change made to the city structure, and those who do not notice any changes in their routine commute, respectively.

The simultaneous display of movements of directly-affected commuters and indirectly-affected commuters and unaffected commuters gives the viewer an immediate appreciation of the impact of a change on city life. One can observe for example, how many commuters are implicated, whether they are affected directly, or indirectly or unaffected. One can observe how a small change to satisfy a few individuals can influence the travel of an entire community. Because of this simultaneous display, the preferred transportation calculator 20 is a useful quick sketch tool to gauge citizens' reaction to a proposed plan.

The icons 30 of citizens are preferably lit up with their respective colours or are illustrated in a bold font when moving along the street network 40 to increase the visual appeal of the display screen 22.

Referring to FIG. 16, some of the icons of citizens are illustrated in a flashing mode 90, designating service-deprived individuals. These individuals are casualties of the last choice made to the city plan. These individuals have no city bus services, no school bus and no car. They are located too far to walk or to bike to city centre. The quantity of these icons appearing on the city map 20 after a choice has been made is an indication of the good or bad consequences of that choice.

A community satisfaction icon 92 and percentage are displayed at the bottom of the right-hand side display screen, as shown in FIG. 8. More precisely, the percentage associated with this icon indicates a portion of the population who has access to key amenities and city services. A higher percentage represents a good choice.

The preferred visual transportation calculator 20 can be operated by a single computer, although a web-base version is preferred. The software for this visual transportation calculator 20 can be downloaded to personal computers of city councilors, consultants, real estate developers, concerned citizens, and operated individually by these computers. As mentioned, the preferred visual transportation calculator 20 is particularly well adapted to conduct public consultations in public places.

The preferred system for holistic approach to city planning is easily tailored for use in one city planning project or another by gathering public information and data of one particular city and its citizens, and arranging this data in databases that are readable by the algorithms included in the preferred system. A meeting with city officials can provide information about the structural element(s) under planning, and the proposed or possible new locations for this or these structural elements. Of course some of the statistics included in household attributes can be retained from one city to the other if the needs of people in both cities are substantially the same. These statistics can also be adjusted from experience acquired during previous work to increase the precision of the preferred system.

As can be appreciated from the present specification, the preferred system for holistic approach to city planning is firstly a city sketch tool to be used by a city's professional planing staff, and secondly, the preferred system is a game-like civic engagement fun tool to be used by citizens in public settings.

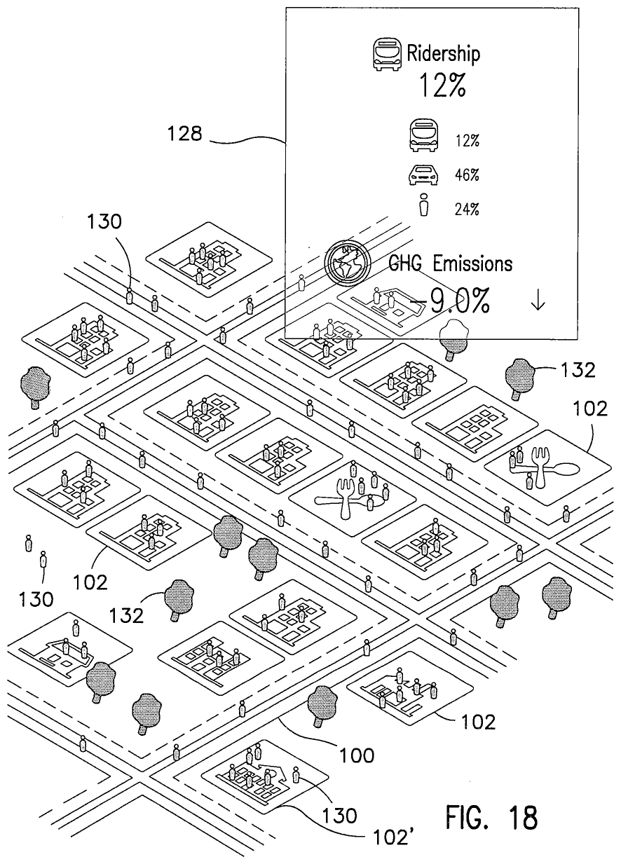

In relation with civic engagement, the preferred system used for this purpose is preferably visually enhanced to provide a more enjoyable experience by citizens. The civic engagement version of the preferred system for holistic approach to city planning is preferably built on three layers, wherein the base layer contains the city's infrastructure including streets 100 and icons 102 of buildings and establishments basically, as can be seen in FIG. 18.

The second layer contains icons 130 of citizens illustrated in a three-dimensional mode, and icons of trees 132 also shown in three-dimensions. Because trees remain one of the most cost-effective way of drawing carbon dioxide from the atmosphere, the icons of trees 132 illustrated on the second layer of the city map gives the viewer a quick appreciation of the sensitivity of the city toward air quality. The display of trees 132 allows a person to do a quick inventory of the pollution reducing capacity of the city being studied.

As mentioned before, the icons of citizens 130 are illustrated in three-dimensions, in movement, and coloured according to their respective “primary use” of the city's infrastructure. Of course, the trees 132 are stationary and are preferably coloured green.

The top layer of the civic engagement version of the preferred system for holistic approach to city planning preferably contains the textual instruction and information windows as exemplified by label 128. The three layers are preferably transparent with the three-dimensional icons of citizens 130 and trees 132 being opaque.

It will be appreciated that the quick sketch tool version of the preferred system for holistic approach to city planning can also be built on three layers, as just explained herein above.

What is claimed is:

1. A system for holistic approach to city planning, comprising:
a computer and a display screen operatively connected to said computer; said computer and display screen being configured for generating an animated display of a street map of a city, icons of commuters moving along streets of said street map from individual departure locations to a common destination on said street map, and;
an algorithm in said computer being configured to repeat a series of travel time calculations for each of said commuter icons wherein said series increases in number at each iteration when said commuter icons approach said common destination, for slowing down processing between said computer and said display screen, consequently and realistically slowing down movements of said commuter icons along said street map when said commuters icons approach said common destination.

2. The system as claimed in claim 1, wherein said algorithm is also configured for slowing down movements of said commuter icons independently of one of said commuter icons to another one of said commuter icons.

3. The system as claimed in claim 2, wherein said algorithm is configured for slowing down movements of said commuter icons according to a different rate of deceleration between said one of said commuter icons and said other one of said commuter icons.

4. The system for holistic approach to city planning, as claimed in claim 1, wherein said processor also comprises a display-speed/clock-time ratio for displaying representative icon speed along said city map, and said algorithm being configured for slowing down said movement of said commuter icons relative to said ratio.

5. The system for holistic approach to city planning, as claimed claim 1, wherein said algorithm is configured to increase work of said computer in an exponential manner when said commuter icons approach said common destination.

6. A method of selectively slowing down processing between a computer and a display screen when displaying movement of icons on a city map displayed on said display screen, between respective departure location and a common destination of said icons on said city map, comprising the step of:
repeating a series of travel-related calculations for each of said icons from said respective departure location to a respective present location of each of said icons, between said departure location and said common destination, wherein said series increases in number at each iteration when said icons approach said common destination.

7. The method as claimed in claim 6, wherein said step of repeating is effected 60 times per second for every commuter for every second of simulation time.

8. The method of selectively slowing down processing between a computer and a display screen, as claimed in claim 6, wherein said step of repeating increases work of said computer in an exponential manner.

9. A system for holistic approach to city planning, comprising:
a computer and a display screen operatively connected to said computer; said computer and display screen being configured for generating an animated display of a street map of a city, icons of commuters moving along streets of said street map from individual departure locations to a common destination on said street map, and;
an algorithm in said computer being configured for gradually slowing individual movements of said icons of commuters when said commuters approach said common destinations.

10. The system for holistic approach to city planning, as claimed in claim 9, wherein said algorithm is further configured for gradually slowing down movements of icons of commuters according to a different rate of deceleration for each of said icons.
